(19) United States
(12) Patent Application Publication
(10) Pub. No.: US 2026/0106626 A1
(43) Pub. Date: Apr. 16, 2026

(54) ANALOG-TO-DIGITAL CONVERSION CIRCUIT AND AN ANALOG-TO-DIGITAL CONVERSION METHOD

(71) Applicant: Renesas Electronics Corporation, Tokyo (JP)

(72) Inventor: Daijiro HARADA, Tokyo (JP)

(21) Appl. No.: 19/299,440

(22) Filed: Aug. 14, 2025

(30) Foreign Application Priority Data
Oct. 15, 2024 (JP) 2024-179634

(51) Int. Cl. H03M 1/46

(52) U.S. Cl. CPC H03M 1/46

(57) ABSTRACT

To provide an analog-to-digital conversion circuit capable of shortening conversion time. An analog-to-digital conversion circuit comprising: a window comparator connected to an analog input circuit; and a comparator connected to the analog input circuit and a digital-to-analog conversion circuit, and a successive approximation register analog-to-digital conversion circuit connected to the window comparator. The successive approximation register analog-to-digital conversion circuit detects the detection range of the window comparator and converts the upper m (m is a natural number) bits using the window comparator.

### CROSS-REFERENCE TO RELATED APPLICATIONS

The disclosure of Japanese Patent Application No. 2024-179634 filed on October 15, 2024, including the specification, drawings and abstract is incorporated herein by reference in its entirety.

### BACKGROUND

The present disclosure relates to an analog-to-digital conversion circuit and an analog-to-digital conversion method.

There are disclosed techniques listed below.

[Patent Document 1] Japanese Unexamined Patent Application Publication No. 5-37376

[Patent Document 2] Japanese Unexamined Patent Application Publication No. 2005-26805

[Patent Document 3] Japanese Unexamined Patent Application Publication No. 2014-57244

[Patent Document 4] Japanese Unexamined Patent Application Publication No. 2023-70600

An analog-to-digital conversion circuit has been developed.

### SUMMARY

However, the successive approximation register analog-to-digital conversion circuit has a problem in that it takes time for conversion. Therefore, the purpose of this disclosure is to provide an analog-to-digital conversion circuit that can shorten the conversion time.

Other objects and novel features will become apparent from the description of this specification and the accompanying drawings.

According to one embodiment, the analog-to-digital conversion circuit includes a window comparator connected to an analog input circuit and a comparator connected to the analog input circuit and a digital-to-analog conversion circuit, and a successive approximation register analog-to-digital conversion circuit connected to the window comparator.

According to the embodiment, an analog-to-digital conversion circuit that can shorten the conversion time is provided.

### BRIEF DESCRIPTION OF THE DRAWINGS

FIG. 1 is a block diagram showing the configuration of a related successive approximation register analog-to-digital conversion circuit.

FIG. 2A is a circuit diagram of an analog-to-digital conversion circuit using a related window comparator.

FIG. 2B is an example of operation using the related window comparator.

FIG. 3 is a block diagram showing the configuration of a related window comparator and a successive approximation register analog-to-digital conversion circuit.

FIG. 4 is a block diagram showing the configuration of the first analog-to-digital conversion circuit of this disclosure.

FIG. 5 is an image diagram of priority interrupt processing using the second analog-to-digital conversion circuit of this disclosure.

### DETAILED DESCRIPTION

For clarity of explanation, the following description and drawings are appropriately omitted and simplified. Each element described in the drawings as a functional block for performing various processes can be configured by hardware such as a CPU (Central Processing Unit), memory, and other circuits, or realized by software such as a program loaded into memory. Therefore, these functional blocks can be realized by hardware, software operating on hardware, or a combination thereof. In the drawings, the same elements are denoted by the same reference numerals, and repetitive descriptions are omitted as necessary.

The aforementioned program can be stored and supplied to a computer using various types of non-transitory computer-readable media. Non-transitory computer-readable media include various types of tangible storage media. Examples of non-transitory computer-readable media include magnetic recording media (e.g., flexible disks, magnetic tapes, hard disk drives), magneto-optical recording media (e.g., magneto-optical disks), CD-ROM (Read Only Memory), CD-R, CD-R/W, semiconductor memory (e.g., mask ROM, PROM (Programmable ROM), EPROM (Erasable PROM), flash ROM, RAM (Random Access Memory)). The program may also be supplied to the computer by various types of transitory computer-readable media. Examples of transitory computer-readable media include electrical signals, optical signals, and electromagnetic waves. Transitory computer-readable media can supply the program to a computer via wired communication paths such as electrical wires and optical fibers, or wireless communication paths.

### (Description of Related Successive approximation register Analog-to-Digital Conversion Circuit)

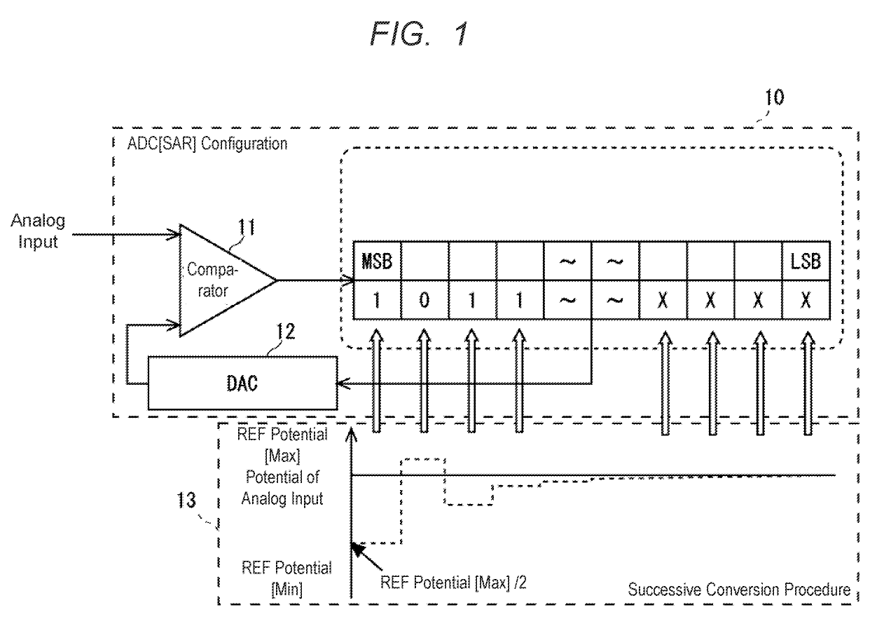

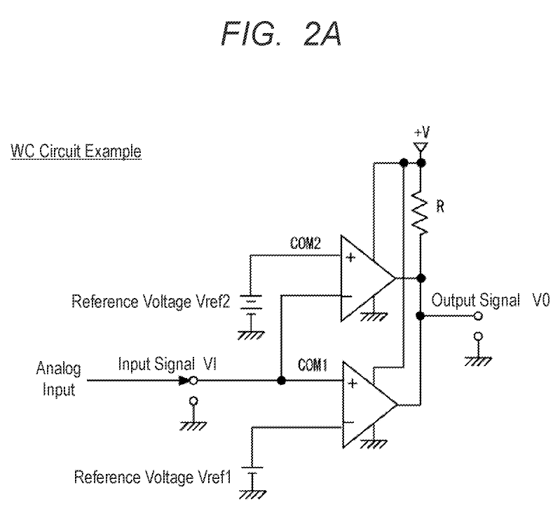

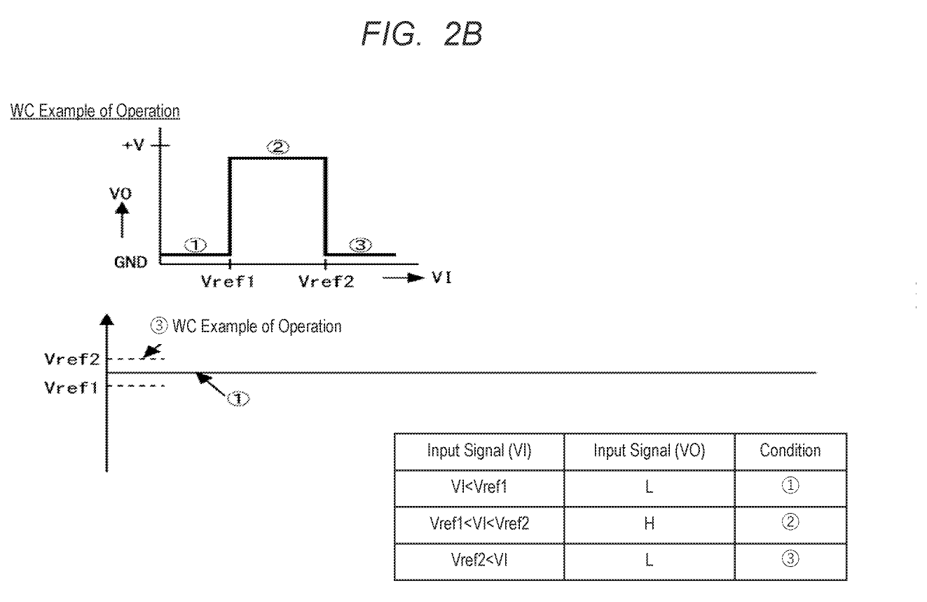

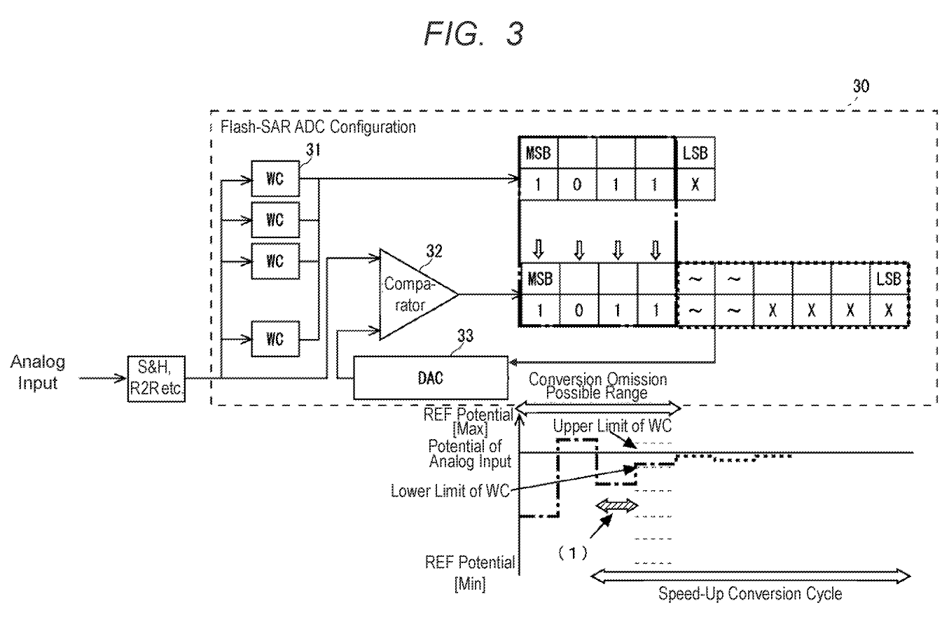

FIG. 1 is a block diagram showing the configuration of a related successive approximation register analog-to-digital conversion circuit. FIG. 2A is a circuit diagram of an analog-to-digital conversion circuit using a related window comparator. FIG. 2B is an example of operation using the related window comparator. FIG. 3 is a block diagram showing the configuration of a related window comparator and a successive approximation register analog-to-digital conversion circuit. The related successive approximation register analog-to-digital conversion circuit will be described with reference to FIGS. 1 to 3.

As shown in FIG. 1, the successive approximation register analog-to-digital conversion circuit 10 includes a comparator 11 connected to an analog input and a DAC (Digital Analog Converter) 12 that generates a Ref (Reference) potential. In a comparator 13, the potential of the analog input and the Ref potential are compared.

As shown in the lower diagram of FIG. 1, initially, the analog input potential is compared with the 1/2 Ref potential. Since the analog input potential is greater than the 1/2 Ref potential, the MSB (Most Significant Bit) is set to 1. Next, a 3/4 potential is generated by the DAC 12, and the analog input potential is compared with the 3/4 Ref potential. Since the analog input potential is smaller than the 3/4 Ref potential, the next bit is set to 0.

In this way, by adding 1/2^n of the Ref potential and comparing it with the analog potential, if it exceeds, the bit is set to 1, and if not, it is set to 0, bringing the Ref potential closer to the analog potential. When all n bits are executed, the analog input potential is converted into an n-bit digital potential.

The successive approximation register analog-to-digital conversion circuit requires n cycles and takes time for conversion.

Therefore, as shown in FIGS. 2A and 2B, there is a window comparator (WC) that shortens the conversion time. The window comparator converts the analog potential between Vref1 and Vref2 into digital potential.

If the analog potential is between Vref1 and Vref2, it can be easily converted to a digital potential, but there is a problem of poor accuracy.

Therefore, as shown in FIG. 3, there is a circuit that performs analog-to-digital conversion by combining a window comparator and a successive approximation register analog-to-digital conversion circuit.

The analog-to-digital conversion circuit 30 includes multiple window comparators 31 connected to the analog input circuit and a comparator 32 connected to the analog input circuit and the DAC 33. The analog-to-digital conversion circuit 30 converts the upper bits with the window comparator 31 and the lower bits with the comparator 32.

As shown in the lower diagram of FIG. 3, when the analog input potential is input, the window comparator 31 determines the upper bits on the MSB side (1). Then, the comparator 32, which inherits the upper bits from the window comparator 31, starts comparison from the set potential. The comparator 32 then performs analog-to-digital conversion only for the lower bits.

In this case, it is not necessary to convert from the Ref potential [Max]/2. Also, the operation cycle of the sample hold (S&H) circuit on the input terminal side, R2R circuit, etc., is necessary (1), but the conversion time can be shortened. However, it is necessary to operate many window comparators in parallel, which increases power consumption. There are also challenges in ensuring the accuracy of the window comparator.

### (Description of the Analog-to-Digital Conversion Circuit of the Present Disclosure)

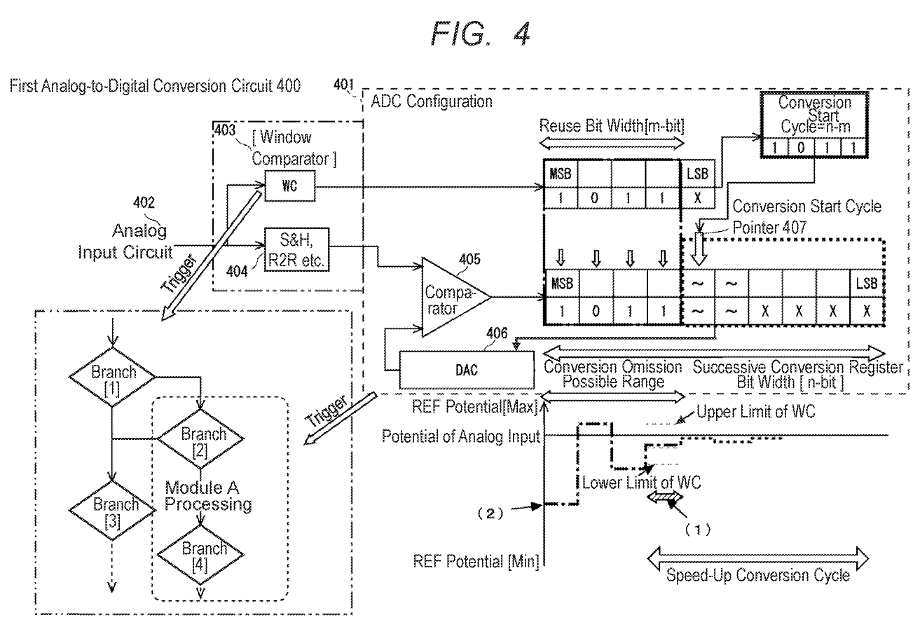

FIG. 4 is a block diagram showing the configuration of the first analog-to-digital conversion circuit of the present disclosure. The analog-to-digital conversion circuit of the present disclosure will be described with reference to FIG. 4.

As shown in FIG. 4, the first analog-to-digital conversion circuit 400 includes one window comparator 403 connected to an external analog input circuit 402, and a sample hold circuit or R2R circuit 404 connected to the external analog input circuit 402. The sample hold circuit is also called a sample & hold circuit (S&H circuit).

The window comparator 403 is connected to the successive approximation register analog-to-digital conversion circuit 401. The window comparator 403 outputs the upper bits. The sample hold circuit or R2R circuit 404 is connected to the comparator 405.

The successive approximation register analog-to-digital conversion circuit 401 includes a comparator 405 and a DAC 406 for generating Ref potential. The comparator 405 is connected at one end to the sample hold circuit or R2R circuit 404 for analog input, and at the other end to the DAC 406 for inputting the Ref potential. The comparator 405 compares the analog input with Ref potential. The comparator 405 outputs the lower bits.

As shown in the lower diagram of FIG. 4, the window comparator 403 includes the analog input potential between the upper Ref potential and the lower Ref potential of the window comparator 403. Therefore, the window comparator 403 can determine the upper bits on the MSB side. Also, the comparator 405 inherits the upper bits from the settings of the window comparator 403 and starts comparison from the set potential.

The conversion start cycle involves the analog-to-digital conversion of the upper m (where m is a natural number) bits using the window comparator 403, which detects the detection range of the window comparator 403. In other words, it determines the upper bits that can be inherited from the setting range of the window comparator 403. The pointer 407 position is specified as the conversion start cycle. The lower n-m bits are converted using the comparator when the total number of bits is n (6). The n-m bits can be set arbitrarily.

By placing a single window comparator 403 outside the successive approximation register analog-to-digital conversion circuit 401 in this manner, there is no need to use multiple window comparators. Additionally, the operation cycle of the window comparator can be concealed by the operation cycle of the input terminal side sample hold circuit or the R-C circuit, thereby reducing the conversion time (1). Moreover, it is not necessary to convert from the Ref potential [Max]/2 (2).

Furthermore, as shown in the lower left diagram of FIG. 4, when multiple system processes are branching, it is possible to execute some system processes while the window comparator 403 is operating by detecting with the window comparator 403. For example, module A can be loaded before the completion of the analog-to-digital conversion. Additionally, another branch may be triggered when the comparator 405 completes the analog-to-digital conversion. For example, branching based on the result of the analog-to-digital conversion is possible. By doing so, it is possible to proceed with the major branching process based on the detection result of the window comparator 403 and preload the data of the expected next processing part, thereby shortening the time.

### Description of the analog-to-digital conversion circuit according to the second embodiment

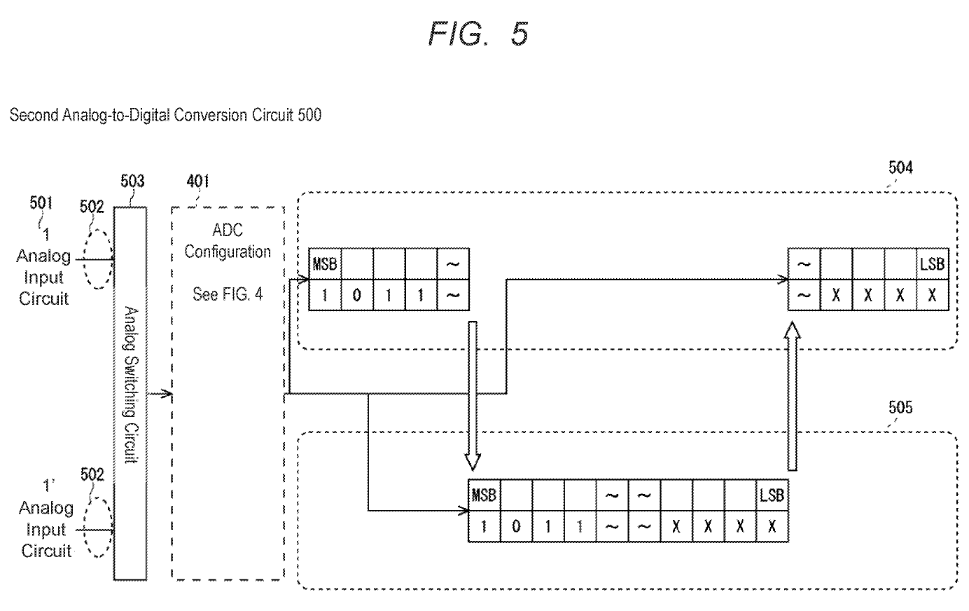

FIG. 5 is an image diagram of priority interrupt processing using the second analog-to-digital conversion circuit of this disclosure. The second analog-to-digital conversion circuit will be described with reference to FIG. 5.

As shown in FIG. 5, the second analog-to-digital conversion circuit 500 includes multiple analog input circuits 501, a sample-and-hold circuit 502 connected to one of the multiple analog input circuits 501, an analog-to-digital conversion circuit 401 of the successive approximation register, and an analog switching circuit 503 connected to the sample-and-hold circuit 502. The multiple analog input circuits 501 are also connected to the window comparator 403.

Consider a case where, during the execution of the analog-to-digital conversion 504 of one analog input, there is a request for the analog-to-digital conversion 505 of a higher priority analog input 1'. Since the sample-and-hold circuit is placed between one of the multiple analog input circuits 501 and the sample-and-hold circuit 503, it is possible to hold the input potential. Therefore, for example, after executing the m-bit analog-to-digital conversion 504 with the window comparator 403, the analog-to-digital conversion 505 can be executed, and then the n-m bit analog-to-digital conversion 504 can be executed again with the successive approximation register analog-to-digital conversion circuit 401.

In this way, the analog-to-digital conversion 504 of the analog input 1 can be interrupted with priority. Depending on the holding characteristics of the sample-and-hold circuit, even higher priority interrupts can be accepted. After completing the conversion of the 1' analog potential, the analog-to-digital conversion of the 1 analog input potential is resumed, which shortens the potential holding period by the sample-and-hold circuit and is expected to improve accuracy. A track-and-hold circuit may be used instead of the sample-and-hold circuit. In this disclosure, an example is shown where a sample-and-hold circuit is connected to one of the multiple analog input circuits, but a sample-and-hold circuit may be connected to each of the multiple analog input circuits.

In this way, when it is possible to hold the input potential with the sample-and-hold circuit, it is possible to execute priority interrupting processing during the analog-to-digital conversion of multiple inputs and resume the analog-to-digital conversion after the interruption.

This disclosure can be applied to appropriate methods. For example, an analog-to-digital conversion method is provided that includes a window comparator connected to an analog input circuit, a comparator connected to the analog input circuit and the digital-to-analog conversion circuit, and a successive approximation register analog-to-digital conversion circuit connected to the window comparator. The analog-to-digital conversion method detects the detection range of the window comparator and converts the upper m (where m is a natural number) bits using the window comparator.

Although the invention made by the inventor has been specifically described based on the embodiment, the present invention is not limited to the embodiment already described, and it is needless to say that various modifications can be made without departing from the gist thereof.

What is claimed is:

1. An analog-to-digital conversion circuit comprising:
a window comparator connected to an analog input circuit; a comparator connected to the analog input circuit and a digital-to-analog conversion circuit; and
a successive approximation register analog-to-digital conversion circuit connected to the window comparator.

2. The analog-to-digital conversion circuit according to claim 1,
wherein the successive approximation register analog-to-digital conversion circuit detects the detection range of the window comparator and converts an upper m (m is a natural number) bits using the window comparator.

3. The analog-to-digital conversion circuit according to claim 2,
wherein the total number of bits is n (n is a natural number), and n-m bits are converted using the comparator.

4. The analog-to-digital conversion circuit according to claim 3,
wherein the n-m bits can be arbitrarily changed.

5. The analog-to-digital conversion circuit according to claim 3 comprising:
a plurality of the analog input circuits; and
a sample hold circuit disposed between the plurality of the analog input circuits and the successive approximation register analog-to-digital conversion circuit,
wherein priority interrupt processing is performed among the plurality of the analog input circuits based on the analog-to-digital conversion by the window comparator or the analog-to-digital conversion by the comparator.

6. The analog-to-digital conversion circuit according to claim 2 having multiple branches of system processing,
wherein some system processing after branching is performed using the analog-to-digital conversion by the window comparator or the analog-to-digital conversion by the comparator as a trigger.

7. An analog-to-digital conversion method of an analog-to-digital conversion circuit comprising:
a window comparator connected to an analog input circuit; a comparator connected to the analog input circuit and a digital-to-analog conversion circuit; and
a successive approximation register analog-to-digital conversion circuit connected to the window comparator, wherein the detection range of the window comparator is detected, and the upper m (m is a natural number) bits are converted using the window comparator.

8. The analog-to-digital conversion method according to claim 7,
wherein the total number of bits is n (n is a natural number), and n-m bits are converted using the comparator.

9. The analog-to-digital conversion method according to claim 8,
wherein the n-m bits can be arbitrarily changed.

10. The analog-to-digital conversion method according to claim 8,
wherein the analog-to-digital conversion circuit comprises: a plurality of the analog input circuits; and a sample hold circuit disposed between the plurality of the analog input circuits and the successive approximation register analog-to-digital conversion circuit, and priority interrupt processing is performed among the plurality of the analog input circuits based on the analog-to-digital conversion by the window comparator or the analog-to-digital conversion by the comparator.

11. The analog-to-digital conversion method according to claim 7,
wherein the analog-to-digital conversion circuit has multiple branches of system processing, and some system processing after branching is performed while advancing the analog-to-digital conversion by the window comparator.
